(19) United States
(12) Patent Application Publication
(10) Pub. No.: US 2015/0170909 A1
(43) Pub. Date: Jun. 18, 2015

(54) METHOD OF MANUFACTURING SEMICONDUCTOR DEVICE AND NON-TRANSITORY COMPUTER-READABLE RECORDING MEDIUM

(71) Applicant: Hitachi Kokusai Electric Inc., Tokyo (JP)

(72) Inventor: Taketoshi SATO, Toyama-shi, (JP)

(73) Assignee: Hitachi Kokusai Electric Inc., Tokyo (JP)

(21) Appl. No.: 14/500,602

(22) Filed: Sep. 29, 2014

Related U.S. Application Data
(62) Division of application No. 14/228,465, filed on Mar. 28, 2014.

(30) Foreign Application Priority Data
Dec. 17, 2013 (JP) 2013-271924
Mar. 3, 2014 (JP) 2014-040430

(51) Int. Cl. H01L 21/02

(52) U.S. Cl. CPC H01L 21/02274

(57) ABSTRACT

A substrate processing system includes a plurality of processing chambers accommodating substrates, a processing gas supply system configured to supply a processing gas sequentially into the plurality of processing chambers, a reactive gas supply system configured to supply an activated reactive gas sequentially into the plurality of processing chambers, a buffer tank installed at the processing gas supply system, and a control unit configured to control the processing gas supply system and the reactive gas supply system such that a time period of supplying the reactive gas into one of the plurality of processing chambers is equal to a sum of a time period of supplying the processing gas into the one of the plurality of processing chambers and a time period of supplying the processing gas into the buffer tank, and the processing gas and the reactive gas are alternately supplied into the plurality of processing chambers.

### CROSS-REFERENCE TO RELATED PATENT APPLICATION

This U.S. non-provisional patent application is a divisional application of U.S. patent application Ser. No. 14/228,465 and claims priority under 35 U.S.C. §119 of Japanese Patent Applications No. 2013-271924 and No. 2014-040430 filed on Dec. 17, 2013 and Mar. 3, 2014, respectively, in the Japanese Patent Office, the entire contents of which are hereby incorporated by reference.

### BACKGROUND OF THE INVENTION

1. Field of the Invention

The present invention relates to a substrate processing system, a method of manufacturing a semiconductor device and a non-transitory computer-readable recording medium.

2. Description of the Related Art

Circuit patterns are being finely miniaturized as large scale integrated circuits (hereinafter referred to as LSIs) become more highly integrated.

In order to integrate a large number of semiconductor devices in a small area, a size of the device should be reduced, and for this, a width and a gap of patterns to be formed should be reduced.

In burying a fine structure by miniaturization in recent times, in particular, in burying oxides in an aperture structure (a groove) having a large depth in a longitudinal direction or a small gap in a horizontal direction, a burying method using a CVD method is approaching its technical limit. In addition, due to miniaturization of transistors, formation of a thin and uniform gate insulating film or gate electrode is needed. Further, in order to increase productivity of semiconductor devices, reduction in processing time per substrate is needed.

### SUMMARY OF THE INVENTION

Since a minimum machining dimension of the semiconductor device represented by an LSI, a dynamic random access memory (DRAM), or a flash memory in recent times is smaller than 30 nm, it is becoming difficult to perform miniaturization, improve manufacturing throughput and reduce a processing temperature, all while maintaining quality. For example, there is a film forming method in which supply/exhaust of a source gas, supply/exhaust of a reactive gas and generation of plasma are sequentially repeated upon formation of a gate insulating film or a gate electrode. In the film forming method, for example, when the plasma is generated, since power regulation, pressure regulation, gas concentration regulation, and so on, are time-consuming, reduction in manufacturing throughput is limited.

The present invention is directed to provide a substrate processing system, a method of manufacturing a semiconductor device and a non-transitory computer-readable recording medium that are capable of improving characteristics of a film formed on a substrate and improving manufacturing throughput.

According to an aspect of the present invention, there is provided a substrate processing system including: a plurality of processing chambers accommodating substrates; a processing gas supply system configured to supply a processing gas into the plurality of processing chambers in sequence; a reactive gas supply system configured to supply an activated reactive gas into the plurality of processing chambers in sequence; a buffer tank installed at the processing gas supply system; and a control unit configured to control the processing gas supply system and the reactive gas supply system to alternately supply the processing gas and the reactive gas into each of the plurality of processing chambers in a manner that a time period of supplying the reactive gas into one of the plurality of processing chambers is equal to a sum of a time period of supplying the processing gas into the one of the plurality of processing chambers and a time period of supplying the processing gas into the buffer tank.

According to another aspect of the present invention, there is provided a method of manufacturing a semiconductor device, the method including: (a) supplying a processing gas into a plurality of processing chambers in sequence for a first time period; (b) supplying the processing gas into a buffer tank installed at a gas supply pipe connected to each of the plurality of processing chambers for a second time period; and (c) supplying an activated reactive gas into the plurality of processing chambers in sequence for a time period equal to a sum of the first time period and the second time period.

According to still another aspect, there is provided a non-transitory computer-readable recording medium storing a program executable by a computer, the program including: (a) supplying a processing gas into a plurality of processing chambers in sequence for a first time period; (b) supplying the processing gas into a buffer tank installed at a gas supply pipe connected to each of the plurality of processing chambers for a second time period; and (c) supplying an activated reactive gas into the plurality of processing chambers in sequence for a time period equal to a sum of the first time period and the second time period.

### BRIEF DESCRIPTION OF THE DRAWINGS

FIG. 1 is a schematic configuration view of a substrate processing apparatus according to an embodiment;

FIG. 2 is a schematic configuration view of a controller of the substrate processing apparatus preferably used in the embodiment;

FIG. 3 is a flowchart showing a substrate processing process according to the embodiment;

FIG. 4a is a view showing an example of a flow of a film-forming process according to the embodiment;

FIG. 4b is a view showing another example of the flow of the film-forming process according to the embodiment;

FIG. 5a is a view showing an example of a cycle of the film-forming process according to the embodiment;

FIG. 5b is a view showing an example of a cycle of a film-forming process according to another embodiment;

FIG. 5c is a view showing an example of a cycle of a film-forming process according to another embodiment;

FIG. 6 is a schematic configuration view of a substrate processing system according to an embodiment;

FIG. 7 is a schematic configuration view of a gas system of the substrate processing system according to the embodiment;

FIG. 8 is a view showing an example of steps in processing chambers of the substrate processing system according to the embodiment;

FIG. 9 is a view showing an example of operating sequences of gas supply valves of the substrate processing system according to the embodiment;

FIG. 10 is a view showing another example of the operating sequences of the gas supply valves of the substrate processing system according to the embodiment;

FIG. 11 is a view showing an example of an operating sequence of valves installed at exhaust systems of the substrate processing system according to the embodiment; and

FIG. 12 is a schematic configuration view of a gas system of a substrate processing system according to another embodiment.

### DETAILED DESCRIPTION OF THE PREFERRED EMBODIMENTS

Hereinafter, embodiments of the present invention will be described.

### Embodiments of the Present Invention

Hereinafter, an embodiment of the present invention will be described with reference to the accompanying drawings.

(1) Configuration of Substrate Processing Apparatus

First, a substrate processing apparatus according to an embodiment of the present invention will be described.

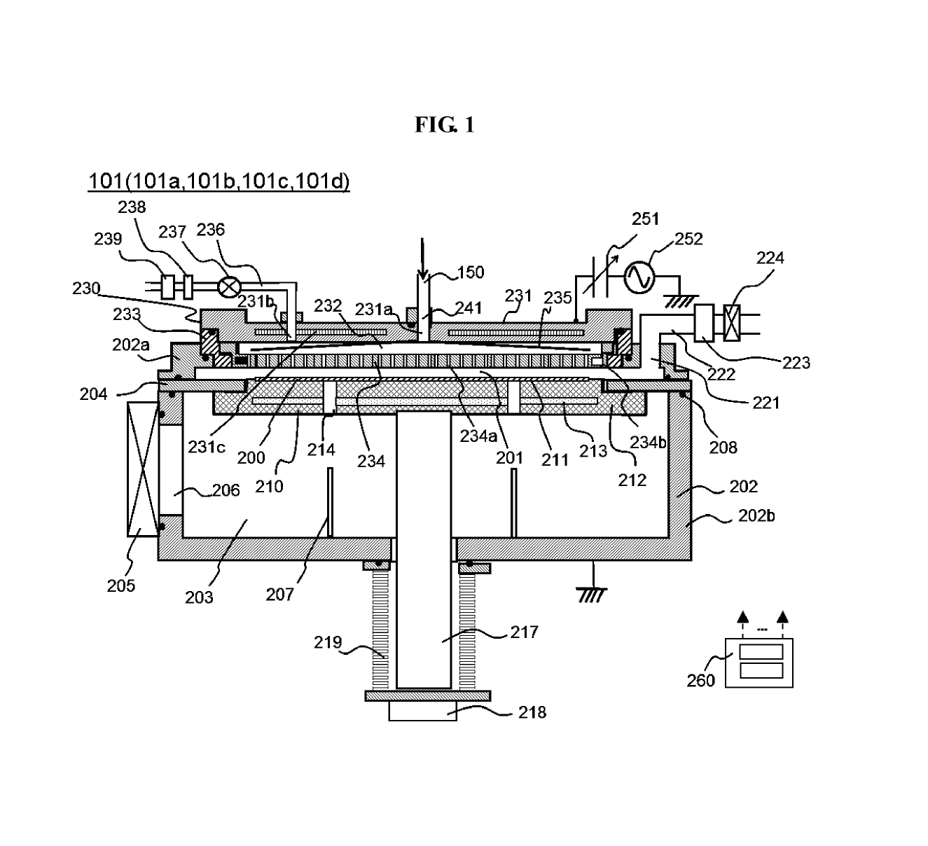

A substrate processing apparatus 101 according to the embodiment will be described. The substrate processing apparatus 101 is a high-k insulating film forming unit, and as shown in FIG. 1, is configured as a single-type substrate processing apparatus. In the substrate processing apparatus, as described above, a process of manufacturing a semiconductor device is performed.

As shown in FIG. 1, the substrate processing apparatus 101 includes a processing container 202. The processing container 202 is constituted by a sealed container having a circular and flat transverse section. In addition, the processing container 202 is formed of a metal material such as aluminum (Al), stainless use steel (SUS), or the like, or quartz. A processing space (a processing chamber) 201 configured to process a wafer 200 serving as a substrate such as a silicon wafer or the like, and a conveyance space 203 are formed in the processing container 202. The processing container 202 is constituted by an upper container 202a and a lower container 202b. A partition plate 204 is installed between the upper container 202a and the lower container 202b. A space surrounded by the upper container 202a and disposed over the partition plate 204 is referred to as the processing space (also referred to as the processing chamber) 201, and a space surrounded by the lower container 202b and disposed under the partition plate is referred to as a conveyance space.

A substrate loading outlet 206 adjacent to a gate valve 205 is installed at a side surface of the lower container 202b, and the wafer 200 moves between the conveyance space 203 and a conveyance chamber (not shown) via the substrate loading outlet 206. A plurality of lift pins 207 are installed at a bottom section of the lower container 202b. In addition, the lower container 202b is grounded.

A substrate support unit 210 configured to support the wafer 200 is installed in the processing chamber 201. The substrate support unit 210 includes a substrate placing surface 211 on which the wafer 200 is placed, and a substrate placing table 212 having the substrate placing surface 211 as an upper surface thereof. In addition, a heater 213 serving as a heating unit may be installed at the substrate support unit 210. As the heating unit is installed, the substrate can be heated to improve quality of a film formed on the substrate. Through-holes 214 through which the lift pins 207 pass may be formed in the substrate placing table 212 at positions corresponding to each of the lift pins 207.

The substrate placing table 212 is supported by a shaft 217. The shaft 217 passes through a bottom section of the processing container 202 and is connected to an elevation mechanism 218 at the outside of the processing container 202. As the elevation mechanism 218 is operated to elevate the shaft 217 and a substrate support frame 212, the wafer 200 placed on the substrate placing surface 211 can be elevated. In addition, a periphery of a lower end section of the shaft 217 is coated by a bellows 219, and the inside of the processing chamber 201 is hermetically sealed.

The substrate placing table 212 is lowered to the substrate support frame such that the substrate placing surface 211 arrives at a position of the substrate loading outlet 206 (a wafer conveyance position) upon conveyance of the wafer 200, and as shown in FIG. 1, upon processing of the wafer 200, the wafer 200 is raised to a processing position in the processing chamber 201 (a wafer processing position).

Specifically, when the substrate placing table 212 is lowered to the wafer conveyance position, upper end sections of the lift pins 207 protrude from an upper surface of the substrate placing surface 211 such that the lift pins 207 support the wafer 200 from beneath. In addition, when the substrate placing table 212 is raised to the wafer processing position, the lift pins 207 are withdrawn from the upper surface of the substrate placing surface 211 such that the substrate placing surface 211 supports the wafer 200 from beneath. In addition, since the lift pins 207 come in direct contact with the wafer 200, the lift pins 207 may be formed of a material such as quartz, alumina, or the like. Further, an elevation mechanism may be installed at the lift pins 207 such that the substrate placing table 212 and the lift pins 207 are operated relative to each other.

[Exhaust System]

An exhaust port 221 serving as a first exhaust unit configured to exhaust an atmosphere in the processing chamber 201 is installed at a side surface of an inner wall of the processing chamber 201 (the upper container 202a). An exhaust pipe 222 is connected to the exhaust port 221, and a pressure regulator 223 such as an auto pressure controller (APC) configured to control the inside of the processing chamber 201 to a predetermined pressure and a vacuum pump (also referred to as an exhaust pump) 224 are sequentially and serially connected to the exhaust pipe 222. A first exhaust unit (an exhaust line) 220 is mainly constituted by the exhaust port 221, the exhaust pipe 222 and the pressure regulator 223. In addition, the vacuum pump 224 may be configured to be included in the first exhaust unit.

[Gas Introduction Port]

A gas introduction port 241 configured to supply various gases into the processing chamber 201 is installed at a ceiling of a shower head 230 (to be described below) installed over the processing chamber 201. A configuration of a gas supply system connected to the gas introduction port 241 will be described below.

[Gas Dispersion Unit]

The shower head 230 serving as the gas dispersion unit is installed between the gas introduction port 241 and the processing chamber 201. The gas introduction port 241 is connected to a lid 231 of the shower head 230), and a gas introduced from the gas introduction port 241 is supplied to a buffer space (also referred to as a buffer chamber) 232 of the shower head 230) via a hole 231a formed in the lid 231.

The lid 231 of the shower head is formed of a conductive metal, and may function as an activation unit (an excitation unit) configured to excite a gas present in the buffer space 232 or the processing chamber 201. Here, an insulating block 233 is installed between the lid 231 and the upper container 202a to insulate the lid 231 from the upper container 202a. Electronic waves (high frequency power or microwaves) may be supplied to an electrode (the lid 231) serving as the activation unit.

The shower head 230 includes a dispersion plate 234 disposed between the buffer space 232 and the processing chamber 201 and configured to disperse the gas introduced from the gas introduction port 241. A plurality of through-holes 234a are formed in the dispersion plate 234. The dispersion plate 234 is disposed to face the substrate placing surface 211.

A gas guide 235 configured to form a flow of the supplied gas is installed in the buffer space 232. The gas guide 235 has a conical shape having a diameter increased from the hole 231a toward the dispersion plate 234. A diameter in a horizontal direction of a lower end of the gas guide 235 is formed farther out than end sections of the through-holes 234a.

An exhaust pipe 236 serving as a second exhaust unit is connected to a side of the buffer space 232 via a shower head exhaust port 231b. A valve 237 configured to switch ON/OFF of exhaust, a pressure regulator 238 such as an auto pressure controller (APC) configured to control the inside of the buffer space 232 to a predetermined pressure and a vacuum pump 239 are sequentially and serially connected to the exhaust pipe 236.

[Supply System]

A common gas supply pipe 150 (150a, 150b, 150c and 150d, which are to be described below) is connected to the gas introduction port 241 connected to the lid 231 of the shower head 230. A processing gas, a reactive gas, and a purge gas, which are to be described below, are supplied from the common gas supply pipe 150.

[Control Unit]

As shown in FIG. 1, the substrate processing apparatus 101 includes a controller 260 configured to control operations of units of the substrate processing apparatus 101.

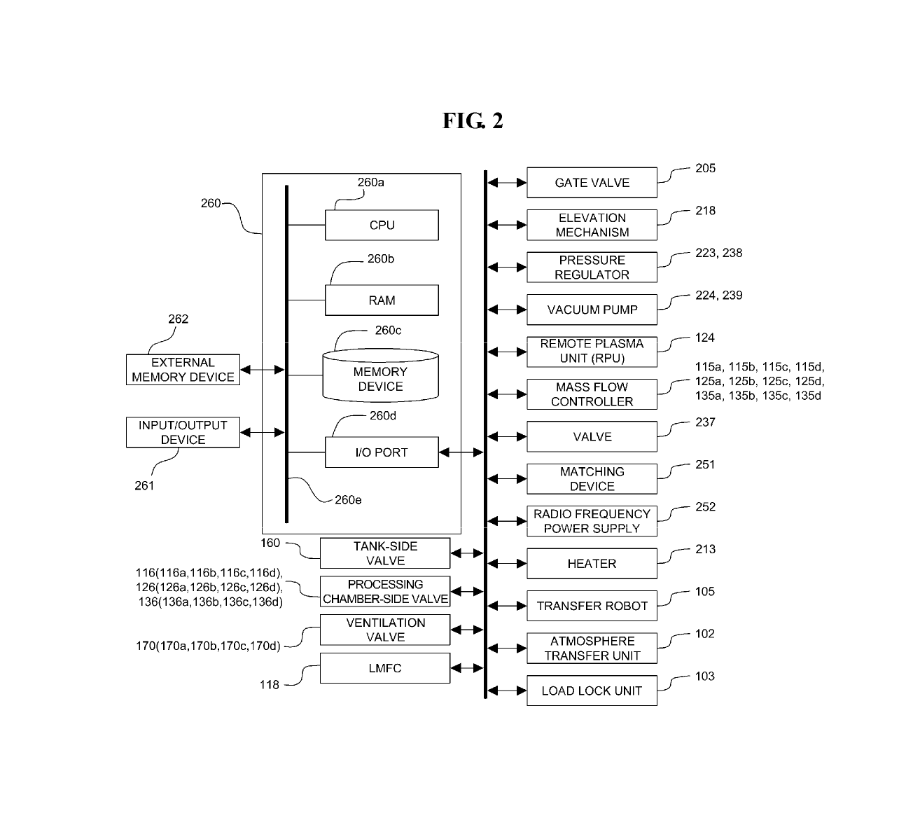

The controller 260 is schematically shown in FIG. 2. The controller 260 serving as a control unit (a control means) is constituted by a computer including a central processing unit (CPU) 260a, a random access memory (RAM) 260b, a memory device 260c and an I/O port 260d. The RAM 260b, the memory device 260c and the I/O port 260d are configured to exchange data with the CPU 260a via an internal bus 260e. An input/output device 261 constituted by a touch panel or the like, or an external memory device 262 is configured to be connected to the controller 260.

The memory device 260c is constituted by a flash memory, a hard disk drive (HDD), or the like. A control program configured to control operations of the substrate processing apparatus, or a program recipe on which substrate processing sequences, conditions, or the like (to be described below) are recorded, is stored in the memory device 260c. In addition, the process recipes, which function as a program, are combined to execute the sequences (to be described below) of the substrate processing process in the controller 260 to obtain a predetermined result. Hereinafter, the program recipes, the control programs, and so on, are generally and simply referred to as programs. In addition, when the term “program” is used in the description, the program may include cases including only a single program recipe, a single control program, or both of these. In addition, the RAM 260b is constituted by a memory region (a work area) in which a program, data, or the like, read by the CPU 260a are temporarily held.

The I/O port 260d is connected to the gate valve 205, the elevation mechanism 218, the heater 213, the pressure regulators 223 and 238, the vacuum pumps 224 and 239, a matching device 251, a radio frequency power supply 252, and so on. In addition, the I/O port 260d may be connected to a transfer robot 105, an atmosphere transfer unit 102, a load lock unit 103, mass flow controllers (MFC) 115a, 115b, 115c, 115d, 125a, 125b, 125c, 125d, 135a, 135b, 135c and 135d, the valve 237, processing chamber-side valves 116 (116a, 116b, 116c and 116d), 126 (126a, 126b, 126c and 126d), and 136 (136a, 136b, 136c and 136d), a tank-side valve 160, ventilation valves 170 (170a, 170b, 170c and 170d), a remote plasma unit 124 (RPU), and so on.

The CPU 260a is configured to read the process recipe from the memory device 260c according to input of a manipulation command or the like from the input/output device 261 while reading and executing the control program from the memory device 260c. In addition, the CPU 260a is configured to control an opening/closing operation of the gate valve 205, an elevation operation of the elevation mechanism 218, a power supply operation to the heater 213, a pressure regulation operation of the pressure regulators 223 and 238, ON/OFF control of the vacuum pumps 224 and 239, a gas activation operation of the remote plasma unit 124, a flow rate control operation of the MFCs 115a, 115b, 115c, 115d, 125a, 125b, 125c, 125d, 135a, 135b, 135c and 135d, gas ON/OFF control of the valve 237, the processing chamber-side valves 116 (116a, 116b, 116c and 116d), 126 (126a, 126b, 126c and 126d), and 136 (136a, 136b, 136c and 136d), the tank-side valve 160, and the ventilation valves 170 (170a, 170b, 170c and 170d), a power matching operation of the matching device 251, ON/OFF control of the radio frequency power supply 252, and so on, according to contents of the read process recipe.

In addition, the controller 260 is not limited to an exclusive computer but may be constituted by a general-purpose computer. For example, the controller 260 according to the embodiment may be constituted by preparing an external memory device 262 in which the above-mentioned program is stored (for example, a magnetic tape, a magnetic disk such as a flexible disk, a hard disk, or the like, an optical disc such as a CD, a DVD, or the like, an optical magnetic disc such as an MO, or a semiconductor memory such as a USB memory, a memory card, or the like), and installing the program in the general computer using the above-mentioned external memory device 262. Further, a unit configured to supply a program to the computer is not limited to the case in which the program is supplied via the external memory device 262. For example, the program may be supplied using a communication means such as the Internet or an exclusive line without the external memory device 262. In addition, the memory device 260c or the external memory device 262 is constituted by a non-transitory computer-readable recording medium. Hereinafter, these are generally and simply referred to as non-transitory computer-readable recording media. Further, the term “non-transitory computer-readable recording medium” used in the description may include only the memory device 260c, only the external memory device 262, or both of these.

(2) Substrate Processing Process

Next, an example of a substrate processing process will be described as an example of forming a titanium nitride (TiN) film using TiCl₄ (titanium chloride) gas serving as a processing gas and NH₃ (ammonia) gas serving as a reactive gas, which is one of manufacturing processes of a semiconductor device.

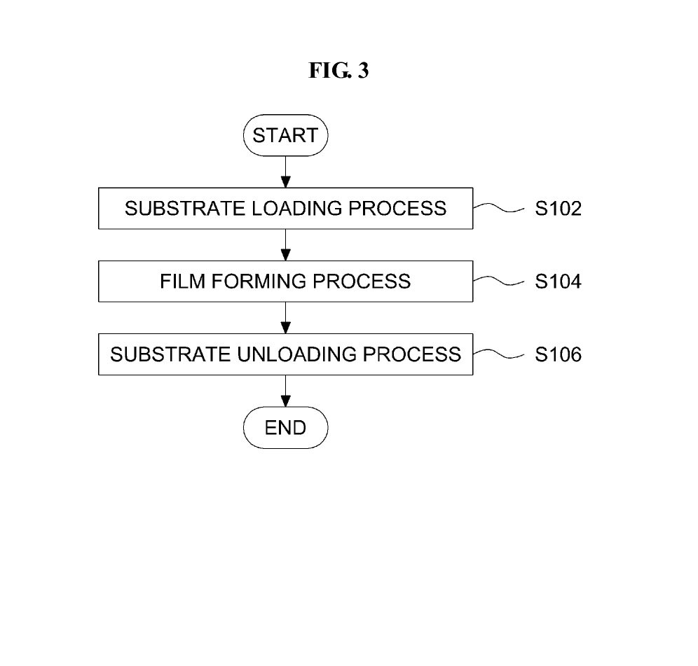

FIG. 3 is a flowchart showing an example of substrate processing performed by a substrate processing apparatus according to the embodiment. As described in FIG. 3, the substrate processing includes at least a substrate loading process (S102), a film-forming process (S104) and a substrate unloading process (S106). Hereinafter, each process will be described in detail.

[Substrate Loading Process (S102)]

Upon film-forming processing, first, the wafer 200 is loaded into the processing chamber 201. Specifically, the substrate support unit 210 is lowered by the elevation mechanism 218 such that the lift pins 207 protrude from the through-holes 214 toward an upper surface of the substrate support unit 210. In addition, after the inside of the processing chamber 201 is regulated to a predetermined pressure, the gate valve 205 is opened and the wafer 200 is placed on the lift pins 207 from the gate valve 205. After placing the wafer 200 on the lift pins 207, as the substrate support unit 210 is raised to a predetermined position by the elevation mechanism 218, the wafer 200 is placed on the substrate support unit 210 from the lift pins 207.

[Film-Forming Process (S104)]

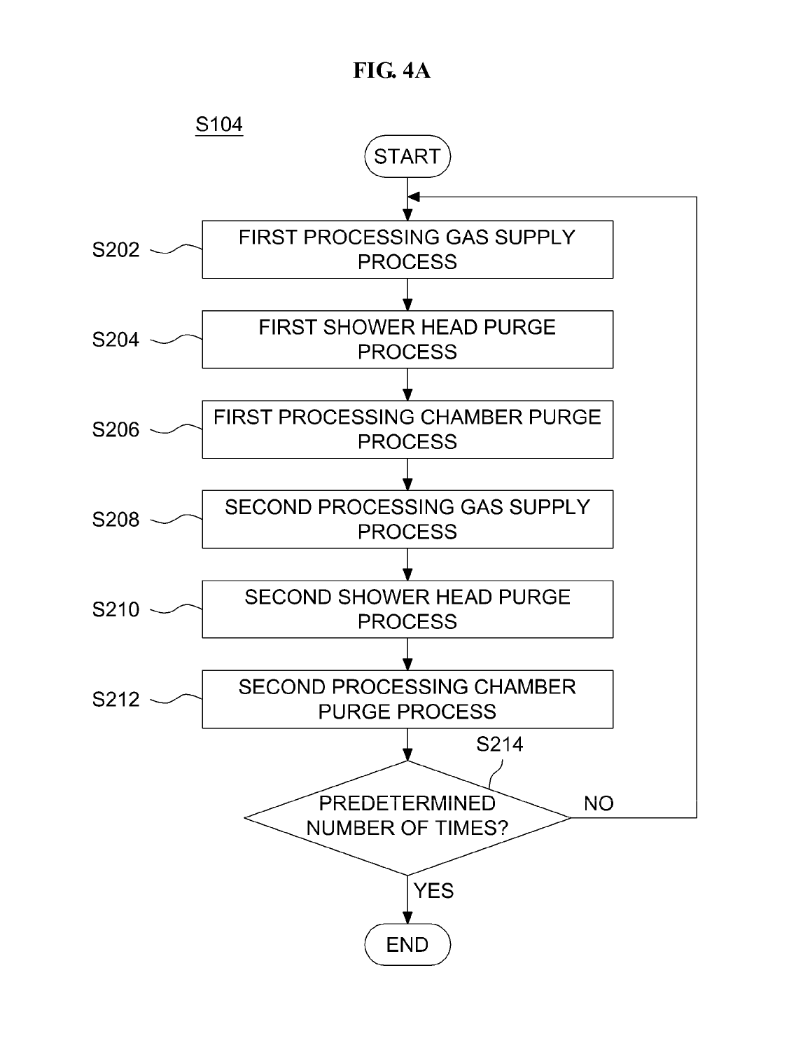

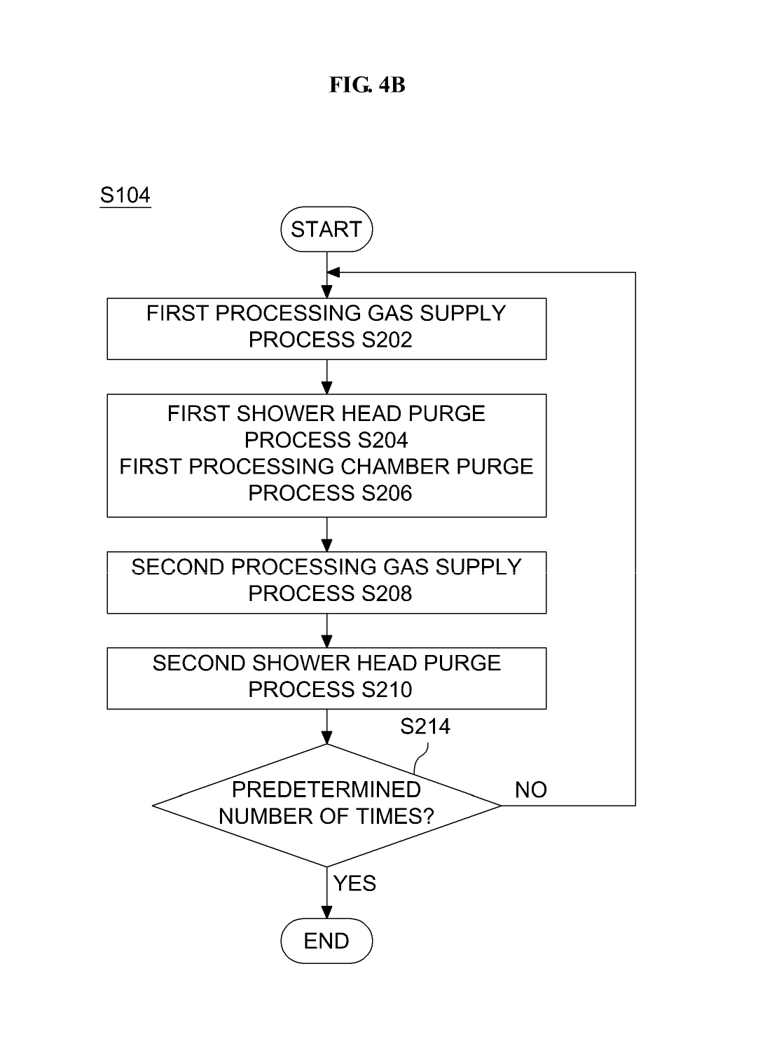

Next, a process of forming a desired film on the wafer 200 is performed. A film-forming process (S104) will be described in detail with reference to FIG. 4a.

After the wafer 200 is placed on the substrate support unit 210 and the atmosphere in the processing chamber 201 is stabilized, steps (S202 to S214) of the process shown in FIG. 4a are performed.

[First Processing Gas Supply Process (S202)]

In a first processing gas supply process (S202), TiCl₄ gas serving as a first processing gas (a source gas) is supplied into the processing chamber 201 from a first processing gas supply system. In addition, the inside of the processing chamber 201 is continuously exhausted by the exhaust system to control the pressure in the processing chamber 201 to a predetermined pressure (a first pressure). Specifically, the processing chamber-side valve 116 (any one of 116a, 116b, 116c and 116d) installed at a first gas supply pipe 111 (any one of 111a, 111b, 111c and 111d) is opened, and the TiCl₄ gas flows through the first gas supply pipe 111. The TiCl₄ gas flows from the first as supply pipe 111, and a flow rate thereof is adjusted by the mass flow controller 115 (any one of 115a, 115b, 115c and 115d). The flow rate-adjusted TiCl₄ gas is supplied into the processing chamber 201 in a pressure-reduced state from the through-holes 234a of the shower head, and exhausted from the exhaust pipe 236. Here, the TiCl₄ gas is supplied to the wafer 200 [a source gas (TiCl₄) supply process]. The TiCl₄ gas is supplied into the processing chamber 201 at a predetermined pressure (a first pressure: for example, 100 Pa to 20,000 Pa). In this way, the TiCl₄ is supplied onto the wafer 200. As the TiCl₄ is supplied, a titanium-containing layer is formed on the wafer 200. The titanium-containing layer is a layer including titanium (Ti) or titanium and chlorine (Cl).

[First Shower Head Purge Process (S204)]

After forming the titanium-containing layer on the wafer 200, the processing chamber-side valve 116 of the first gas supply pipe 111 is closed, and supply of the TiCl₄ gas is stopped. Here, the valve 237 of the exhaust pipe 236 is opened and a gas present in the buffer space 232 is exhausted from the exhaust pump 239 via the exhaust pipe 236. Here, the exhaust pump 239 is previously operated. A pressure (an exhaust conductance) in the exhaust pipe 236 and the shower head 230 is controlled by the APC valve 238. The exhaust conductance controls an opening/closing valve of the valve 126a and the vacuum pump 239 such that the exhaust conductance in the buffer space 232 from the first exhaust system is higher than the conductance of the exhaust pump 224 via the processing chamber 201. A gas flow directed toward the shower head exhaust port 231b from a center of the buffer space 232 is formed by the above-mentioned adjustment. Accordingly, the gas stuck to a wall of the buffer space 232 or the gas floating in the buffer space 232 can be exhausted from the first exhaust system without entering the processing chamber 201. In addition, the pressure in the buffer space 232 and the pressure (the exhaust conductance) of the processing chamber 201 may be adjusted to suppress a back flow of the gas from the processing chamber 201 into the buffer space 232.

In addition, here, the purge includes a pressing-out operation of the processing gas by the supply of the inert gas in addition to simple vacuum suction and gas discharge. Accordingly, the discharge operation may be performed by supplying the inert gas into the buffer space 232 and pressing out the remaining gas through the purge process. In addition, the vacuum suction and the supply of the inert gas may be combined. In addition, the vacuum suction and the supply of the inert gas may be alternately performed.

[First Processing Chamber Purge Process (S206)]

After a predetermined time elapses, an operation of the exhaust pump 224 of the second exhaust system is continuously performed and an opening angle of the APC valve 223 is continuously adjusted such that the exhaust conductance from the second exhaust system in the processing space becomes higher than the exhaust conductance from the first exhaust system via the shower head 230. A gas flow directed toward the second exhaust system via the processing chamber 201 can be formed by the above-mentioned adjustment to exhaust the gas remaining in the processing chamber 201. In addition, here, as the processing chamber-side valves 136 (136a, 136b, 136c and 136d) are opened and the MFCs 135 (135a, 135b, 135c and 135d) can be adjusted to supply the inert gas to securely supply the inert gas onto the substrate, removal efficiency of the gas remaining on the substrate is increased.

The inert gas supplied in the processing chamber purge process removes a titanium component that is not coupled to the wafer 200 in the first processing gas supply process (S202) from above the wafer 200. In addition, the TiCl₄ gas remaining in the shower head 230 may be removed by opening the valve 237 and controlling the pressure regulator 238 and the vacuum pump 239. After a predetermined time elapses, the valve 136 is closed, the valve 237 is closed while stopping the supply of the inert gas, and a space between the shower head 230 and the vacuum pump 239 is blocked.

More preferably, after a predetermined time elapses, the valve 237 may be closed while continuously operating the exhaust pump 224 of the second exhaust system. Accordingly, since a flow directed toward the second exhaust system via the processing chamber 201 is not influenced by the first exhaust system, the inert gas can be more securely supplied on the substrate and removal efficiency of the gas remaining on the substrate can be further improved.

In addition, the purge of the processing chamber also includes a pressing-out operation of the processing gas by the supply of the inert gas in addition to simple vacuum suction and gas discharge. Accordingly, the discharge operation may be performed by supplying the inert gas into the buffer space 232 and pressing out the remaining gas in the purge process. In addition, the vacuum suction and the supply of the inert gas may be combined. Further, the vacuum suction and the supply of the inert gas may be alternately performed.

In addition, here, the gas remaining inside the processing chamber 201 or inside the shower head 230 may not be completely removed, and the inside of the processing chamber 201 may not be completely purged. When an amount of the gas remaining in the processing chamber 201 is minute, there is no bad influence in the process performed after that. Here, a flow rate of N₂ gas supplied into the processing chamber 201 need not become a large flow rate either, and for example, the purge may be performed such that there is no bad influence in the next process by supplying an amount similar to a capacity of the processing chamber 201. As described above, as the inside of the processing chamber 201 is not completely purged, a purge time can be reduced to improve manufacturing throughput. In addition, consumption of the N₂ gas can be suppressed to a necessary minimum limit.

A temperature of the heater 213 at this time is set to a range of 200° C. to 750° C., preferably 300° C. to 600° C., and more particularly 300° C. to 550° C., similar to that upon the supply of the source gas onto the wafer 200. A supply flow rate of the N₂ gas serving as the purge gas supplied from the inert gas supply system is set to a flow rate within a range of, for example, 100 sccm to 20,000 sccm. A rare gas such as Ar, He, Ne, Xe, or the like, in addition to N₂ gas, may be used as the purge gas.

[Second Processing Gas Supply Process (S208)]

After the first processing chamber purge process, the valve 126a is opened, and activated ammonia gas serving as a second processing gas (a reactive gas) is supplied into the processing chamber 201 via the remote plasma unit (RPU) 124 serving as an activation unit (an excitation unit), the gas introduction port 241, the buffer chamber 232, and the plurality of through-holes 234a. Since the ammonia gas is supplied into the processing chamber via the buffer chamber 232 and the through-holes 234a, the gas can be uniformly supplied onto the substrate. For this reason, a film thickness can be uniformized.

Here, the mass flow controller 125a is adjusted such that the flow rate of the NH₃ gas becomes a predetermined flow rate. In addition, the supply flow rate of the NH₃ gas is, for example, 100 sccm to 10,000 sccm. Further, as the opening angle of the APC valve 223 is appropriately adjusted, the pressure in the processing container 202 becomes a predetermined pressure. In addition, when the NH₃ gas flows through the RPU 124, the RPU 124 is turned ON to be controlled to activate (excite) the NH₃.

When the excited NH₃ gas is supplied onto the titanium-containing layer formed on the wafer 200, the titanium-containing layer is modified. For example, a modified layer containing the element titanium or the element nitrogen is formed.

The modified layer is formed to a predetermined thickness, a predetermined distribution and an intrusion depth of a predetermined nitrogen ingredient or the like with respect to the titanium-containing layer according to the pressure in the processing chamber 201, the flow rate of the NH₃ gas, the temperature of the wafer 200, and the power supply state of the RPU 124.

After a predetermined time elapses, the valve 126 is closed and the supply of the NH₃ gas is stopped.

[Second Shower Head Purge Process (S210)]

After the supply of the NH₃ gas is stopped, the valve 237 is opened and the atmosphere in the shower head 230 is exhausted. Specifically, the atmosphere in the buffer chamber 232 is exhausted. Here, the vacuum pump 239 is previously operated.

The opening angle of the valve 237 or the opening angle of the APC valve 238 is adjusted such that the exhaust conductance from the first exhaust system in the buffer chamber 232 is higher than the conductance of the exhaust pump 224 via the processing chamber 201 from the second exhaust system. A gas flow directed toward the shower head exhaust port 231b from the buffer chamber 232 is formed by the above-mentioned adjustment. As a result, the gas stuck to the wall of the buffer chamber 232 or the gas floating in the buffer space is exhausted from the first exhaust system without entering the processing chamber 201.

The purge of the second shower head purge process may also be configured to be similar to the purge of the first shower head purge process.

[Second Processing Chamber Purge Process (S212)]

After a predetermined time elapses, the opening angles of the APC valves 223 and 238 are adjusted such that the exhaust conductance from the second exhaust system in the processing space becomes higher than the exhaust conductance from the first exhaust system via the shower head 230 while operating the exhaust pump 224 of the second exhaust system. A gas flow directed toward the second exhaust system via the processing chamber 201 can be formed by the above-mentioned adjustment to remove the gas remaining on the wafer 200. In addition, the inert gas supplied into the buffer chamber 232 can be supplied onto the wafer 200 by opening the valve 136 and supplying the inert gas, and removal efficiency of the gas remaining on the substrate can be improved.

The inert gas supplied in the processing chamber purge process removes the NH₃ gas that is not coupled to the titanium-containing layer in the second processing gas supply process (S212) from the wafer 200. In addition, the NH₃ gas remaining in the shower head 230 is also removed. After a predetermined time elapses, the valve 136 is closed, the valve 237 is closed while stopping the supply of the inert gas, and a space between the shower head 230 and the vacuum pump 239 is blocked.

More specifically, after a predetermined time elapses, the valve 237 may be closed while continuously operating the exhaust pump 224 of second exhaust system. As a result, since the gas remaining in the buffer chamber 232 or the supplied inert gas has a flow directed toward the second exhaust system via the processing chamber 201 not influenced by the first exhaust system, the inert gas can be more securely supplied onto the substrate, and thus removing efficiency of the remaining gas that is not completely reacted with the first gas on the substrate is further increased.

As described above, since the purge process of the processing chamber is performed in a state in which the gas remaining in the shower head 230 is removed by continuously performing the purge process of the processing chamber after the purge process of the shower head, supply of the gas remaining in the processing chamber 201 from the shower head 230 and sticking of the remaining gas to the wafer 200 can be prevented.

In addition, when the remaining processing gas or reactive gas is within an allowable range, as shown in FIG. 4b, the purge process of the shower head and the purge process of the processing chamber may be simultaneously performed. As a result, the purge time can be reduced and manufacturing throughput can be improved.

Further, the second processing chamber purge process may be configured to be similar to the first processing chamber purge process.

[Determination Process (S214)]

After the second processing chamber purge process (S212) is completed, the controller 260 determines whether the process (S202 to S212) is performed a predetermined number of times. That is, the controller 260 determines whether a film having a desired thickness is formed on the wafer 200.

When the process is not performed the predetermined number of times (No), a cycle of the process (S202 to S212) is repeated. When the process is performed the predetermined number of times (Yes), the film-forming process (S104) is terminated.

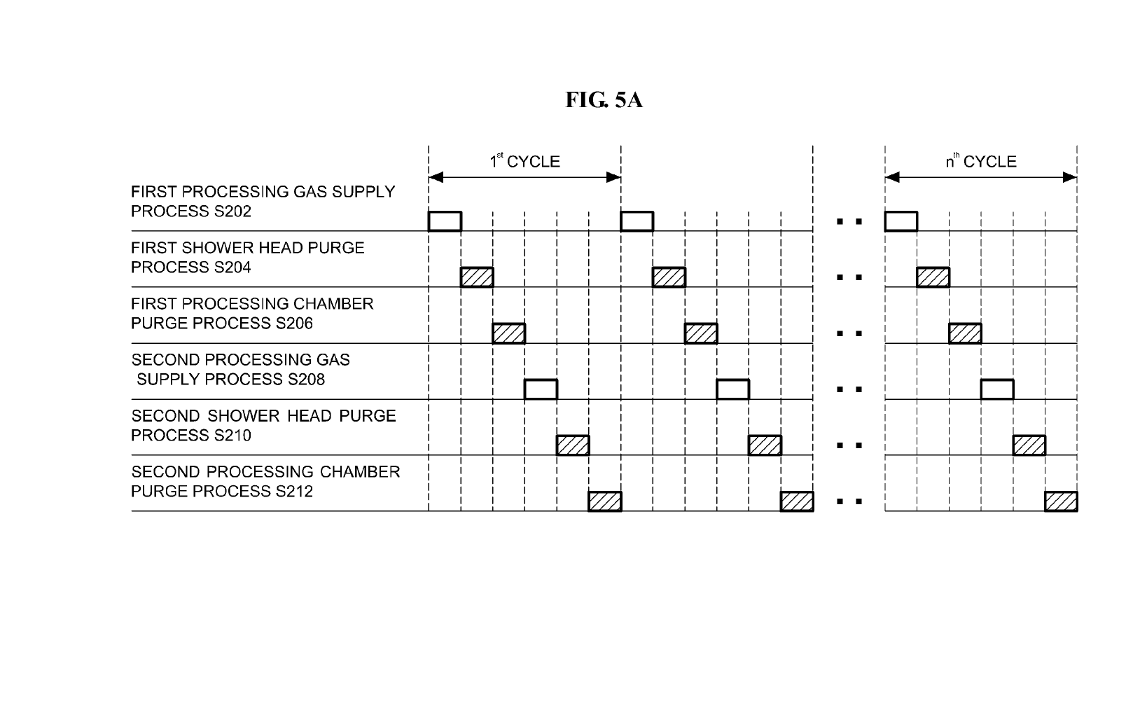

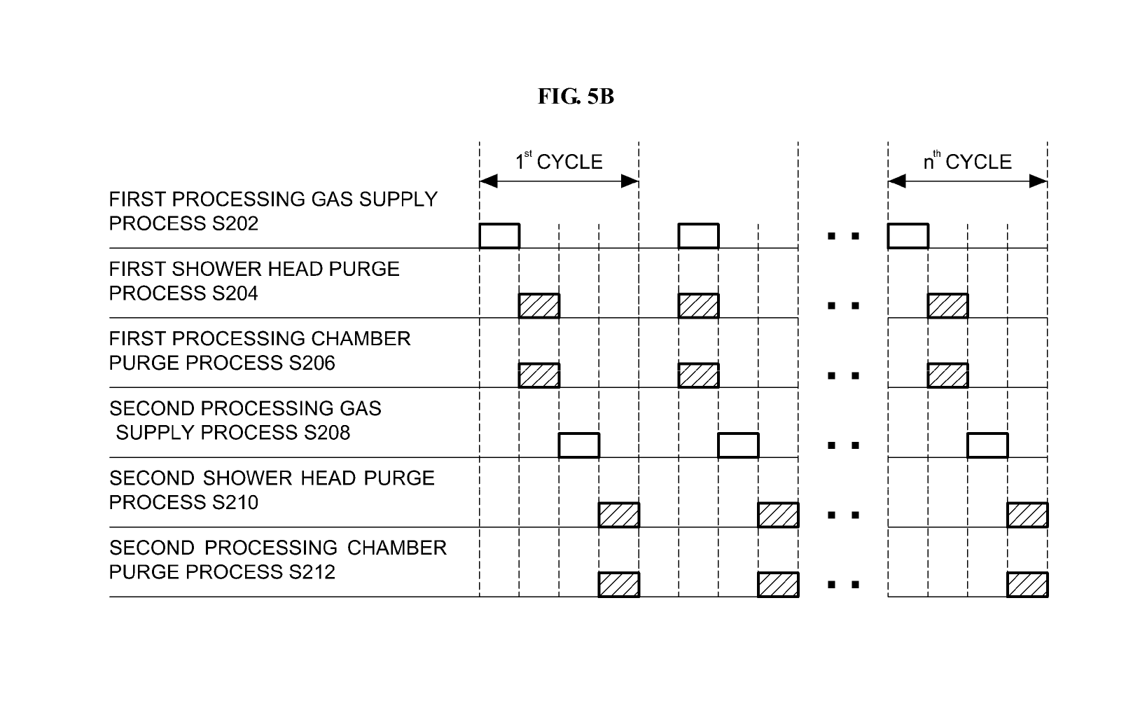

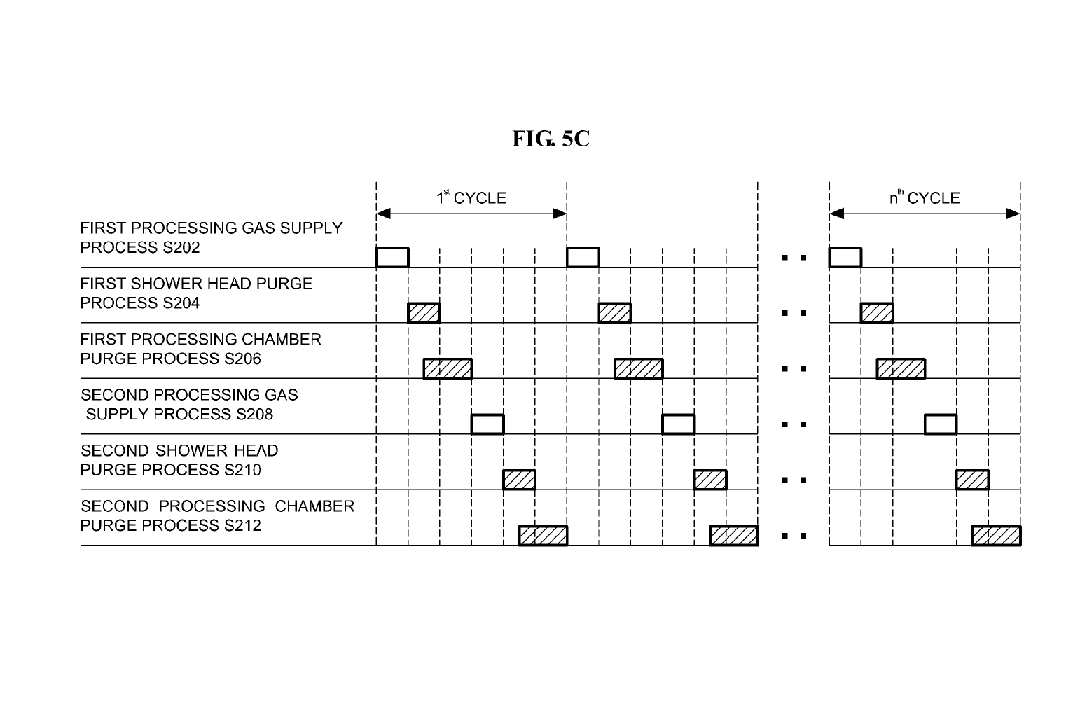

Here, an example of a cycle of the process (S202 to S212) will be described with reference to FIGS. 5a to 5c. FIG. 5a shows a cycle in which the processes are sequentially performed as described above. FIG. 5b shows a cycle configured such that the first shower head purge process (S204) and the first processing chamber purge process (S206) are substantially simultaneously performed and the second shower head purge process (S210) and the second processing chamber purge process (S212) are substantially simultaneously performed. As described above, since the purge time can be reduced by substantially simultaneously purging the shower head and the processing chamber, improvement of the manufacturing throughput can be expected. FIG. 5c shows a cycle configured such that the first processing chamber purge process (S206) starts before the first shower head purge process (S204) is terminated and the second processing chamber purge process (S212) starts before the second shower head purge process (S210) is terminated. Accordingly, the processing gas or the reactive gas remaining in the processing chamber 201 can be further reduced.

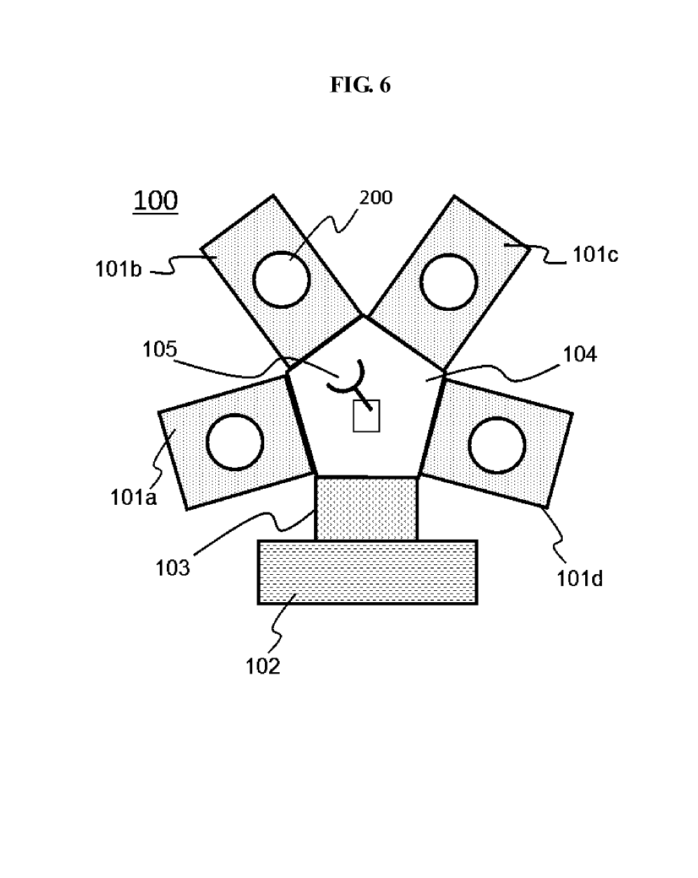

Next, a gas supply system, a cycle of each process, and a gas supply sequence in a substrate processing system in which a plurality of substrate processing apparatuses 101 are installed will be described with reference to FIGS. 6, 7, 8 and 9.

Here, as shown in FIG. 6, the substrate processing system 100 in which four substrate processing apparatuses 101a, 101b, 101c and 101d are installed in a vacuum conveyance chamber 104 will be described. Each of the substrate processing apparatuses is configured such that the wafers 200 are sequentially conveyed by the transfer robot 105 installed in the vacuum conveyance chamber 104. In addition, the wafers 200 are loaded into the vacuum conveyance chamber 104 from the atmosphere conveyance unit 102 via the load lock unit 103. Further, while the case in which four substrate processing apparatuses are installed has been described, two or more substrate processing apparatuses may be installed, or five or more substrate processing apparatuses may be installed.

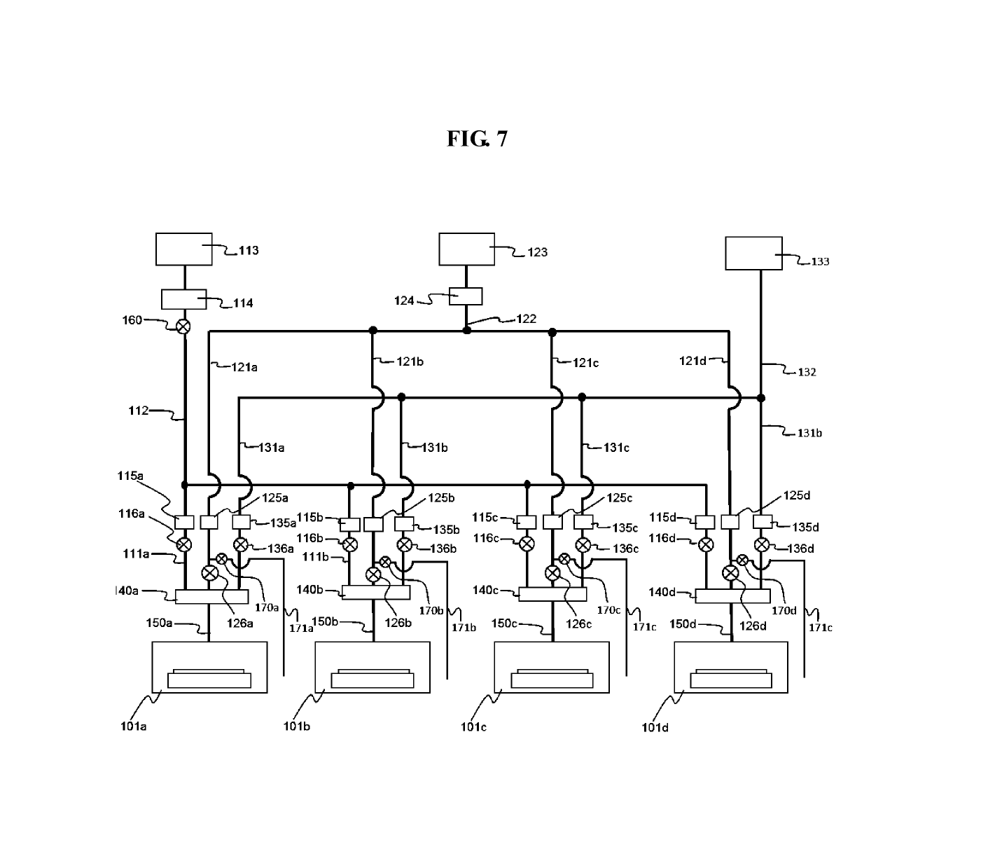

Next, a gas supply system installed at the substrate processing system 100 will be described with reference to FIG. 7. The gas supply system is constituted by a first gas supply system (a processing gas supply system), a second gas supply system (a reactive gas supply system), a third gas supply system (a purge gas supply system), and so on. A configuration of the gas supply system will be described.

[First Gas Supply System]

As shown in FIG. 7, a buffer tank 114, the mass flow controllers (MFCs) 115a, 115b, 115c and 115d, and the processing chamber-side valves 116 (116a, 116b, 116c and 116d) are installed between the substrate processing apparatuses from a processing gas source 113. In addition, these are connected to a processing gas common pipe 112, processing gas supply pipes 111a, 111b, 111c and 111d, and so on. A first gas supply system is constituted by the buffer tank 114, the processing gas common pipe 112, the MFCs 115a, 115b, 115c and 115d, the processing chamber-side valves 116 (116a, 116b, 116c and 116d), and the processing gas supply pipes 111a, 111b, 111c and 111d. In addition, the processing gas source 113 may be configured to be included in the first gas supply system. Further, the number of components may be increased or reduced according to the number of substrate processing apparatuses installed at the substrate processing system.

[Second Gas Supply System]

As shown in FIG. 7, the remote plasma unit (RPU) 124 serving as the activation unit, the MFCs 125a, 125b, 125c and 125d and the processing chamber-side valves 126 (126a, 126b, 126c and 126d) are installed between the substrate processing apparatuses from a reactive gas source 123. Each of these is connected to a reactive gas common pipe 122, reactive gas supply pipes 121a, 121b, 121c, 121d, and so on. A second gas supply system is constituted by the RPU 124, the MFCs 125a, 125b, 125c and 125d, the processing chamber-side valves 126 (126a, 126b, 126c and 126d), the reactive gas common pipe 122, the reactive gas supply pipes 121a, 121b, 121c and 121d, and so on. In addition, the reactive gas source 123 may be configured to be included in the second gas supply system. Further, the number of components may be increased or reduced according to the number of substrate processing apparatuses installed at the substrate processing system.

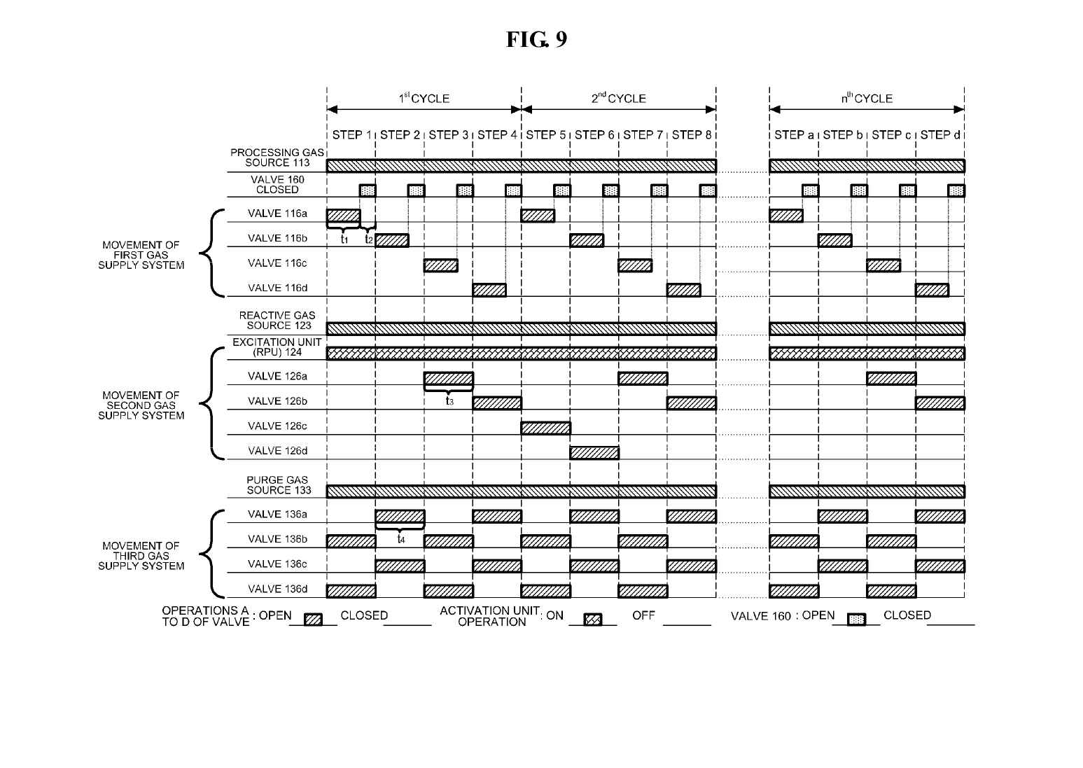

In addition, ventilation lines 171a, 171b, 171c and 171d and ventilation valves 170 (170a, 170b, 170c and 170d) may be installed in front of the processing chamber-side valves 126 (126a, 126b, 126c and 126d) to exhaust the reactive gas. A deactivated reactive gas or a reactivity-reduced reactive gas may be discharged by installing the ventilation lines without passing through the processing chamber. For example, the reactive gas may not be supplied to any substrate processing chamber until step 3 of FIG. 9 (to be described below), and a process of discharging the activity-reduced reactive gas remaining in the gas supply pipes 121a, 121b, 121c, 121d may be provided. Accordingly, processing uniformity between the substrate processing apparatuses can be improved.

[Third Gas Supply System (Purge Gas Supply System)]

As shown in FIG. 7, the MFCs 135a, 135b, 135c and 135d, the processing chamber-side valves 136 (136a, 136b, 136c and 136d), and so on, are installed between the substrate processing apparatuses from a purge gas source (an inert gas source) 133. Components of these are connected to a purge gas (inert gas) common pipe 132, purge gas (inert gas) supply pipes 131a, 131b, 131c and 131d, and so on. A third gas supply system is constituted by the MFCs 135a, 135b, 135c and 135d, the processing chamber-side valves 136 (136a, 136b, 136c and 136d), the inert gas common pipe 132, the inert gas supply pipes 131a, 131b, 131c and 131d, and so on. In addition, the purge gas source (the inert gas source) 133 may be configured to be included in the third gas supply system (purge gas supply system). In addition, the number of components may be increased or reduced according to the number of substrate processing apparatuses installed at the substrate processing system.

[Processing Process in Each Substrate Processing Apparatus]

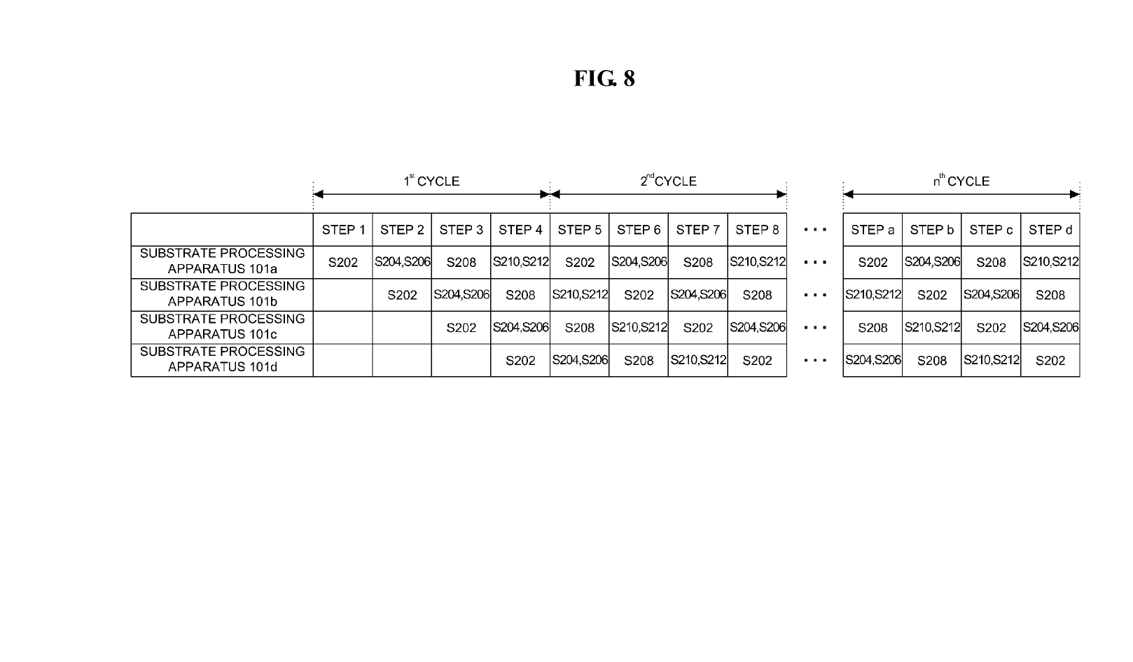

Next, the processing processes of the steps in the four substrate processing apparatuses will be described with reference to FIG. 8.

[Step 1]

The first processing gas supply process (S202) is performed in the substrate processing apparatus (101a).

[Step 2]

The first shower head purge process (S204) and the first processing chamber purge process (S206) are performed in the substrate processing apparatus 101a, and the first processing gas supply process (S202) is performed in the substrate processing apparatus 101b.

[Step 3]

The second processing gas supply process (S208) is performed in the substrate processing apparatus 101a, the first shower head purge process (S204) and the first processing chamber purge process (S206) are performed in the substrate processing apparatus 101b, and the first processing gas supply process (S202) is performed in the substrate processing apparatus 101c.

[Step 4]

The second shower head purge process (S210) and the second processing chamber purge process (S212) are performed in the substrate processing apparatus 101a, the second processing gas supply process (S208) is performed in the substrate processing apparatus 101b, the first shower head purge process (S204) and the first processing chamber purge process (S206) are performed in the substrate processing apparatus 101c, and the first processing gas supply process (S202) is performed in the substrate processing apparatus 101d.

As described above, the processing gas supply process, the purge process, the reactive gas supply process and the purge process are performed in each step in each of the substrate processing apparatuses in this cycle.

Hereinafter, valve operations of the gas supply system in each step will be described with reference to FIG. 9.

The processing gas source 113, the reactive gas source 123 and the purge gas source 133 are maintained in an ON state while performing at least the film-forming process (S104). In addition, the activation unit 124 is also maintained in the ON state while the reactive gas is supplied from the reactive gas source 123. The first gas supply system, the second gas supply system and the third gas supply system perform the opening/closing operations of the valves with the above-mentioned operations of FIG. 8.

Here, preferably, when each of the processing chamber-side valves 116 (116a, 116b, 116c and 116d) is opened for a predetermined first time t₁ and then closed, the processing gas in the buffer tank 114 is buffered for a predetermined second time t₂. As described above, as the processing gas is temporarily supplied into the buffer tank 114, a pressure variation of an upstream side of the gas supply system or a pressure variation in the pipe can be attenuated, and a supply amount of the processing gas into the processing chambers can be uniformized.

Preferably, timing is adjusted such that a sum of the predetermined first time t₁ and the predetermined second time t₂ is equal to any one or both of a supply time t₃ of the reactive gas and a supply time t₄ of the inert gas.

More preferably, the predetermined second time t₂ is set to be smaller than the predetermined first time t₁. As a result, since the pressure of the buffer tank 114 can be lowered to be equal to or less than the predetermined pressure, an increase or decrease in pressure can be further attenuated.

In addition, preferably, the buffering in the buffer tank 114 may be performed simultaneously with closing of the valves 116 (116a, 116b, 116c and 116d).

In addition, preferably, the tank-side valve 160 may be closed simultaneously with closing of the valves 116, the supply of the processing gas into the processing chambers may be stopped, and the processing gas may be supplied into the buffer tank 114.

In addition, the tank-side valve 160 may be installed at a rear end of the buffer tank 114 of the first gas supply system, and the tank-side valve 160 may be closed when the processing chamber-side valves 116 (116a, 116b, 116c and 116d) are closed. In addition, the tank-side valve 160 may be closed after a predetermined time from when the processing chamber-side valves 116 are closed. After the processing gas is filled in the processing gas common pipe 112 to a predetermined pressure by a time difference, the gas into the buffer tank 114 can be buffered to further attenuate the pressure. Since a gas supply amount to the other processing chamber 201 can be uniformly maintained immediately after the inside of the processing gas common pipe 112 is filled at a predetermined pressure and any one of the processing chamber-side valve 116 is opened, the gas supply amount in the processing chambers can be uniformly maintained even when lengths of the gas pipes from the first gas supply system to the processing chambers differ from each other.

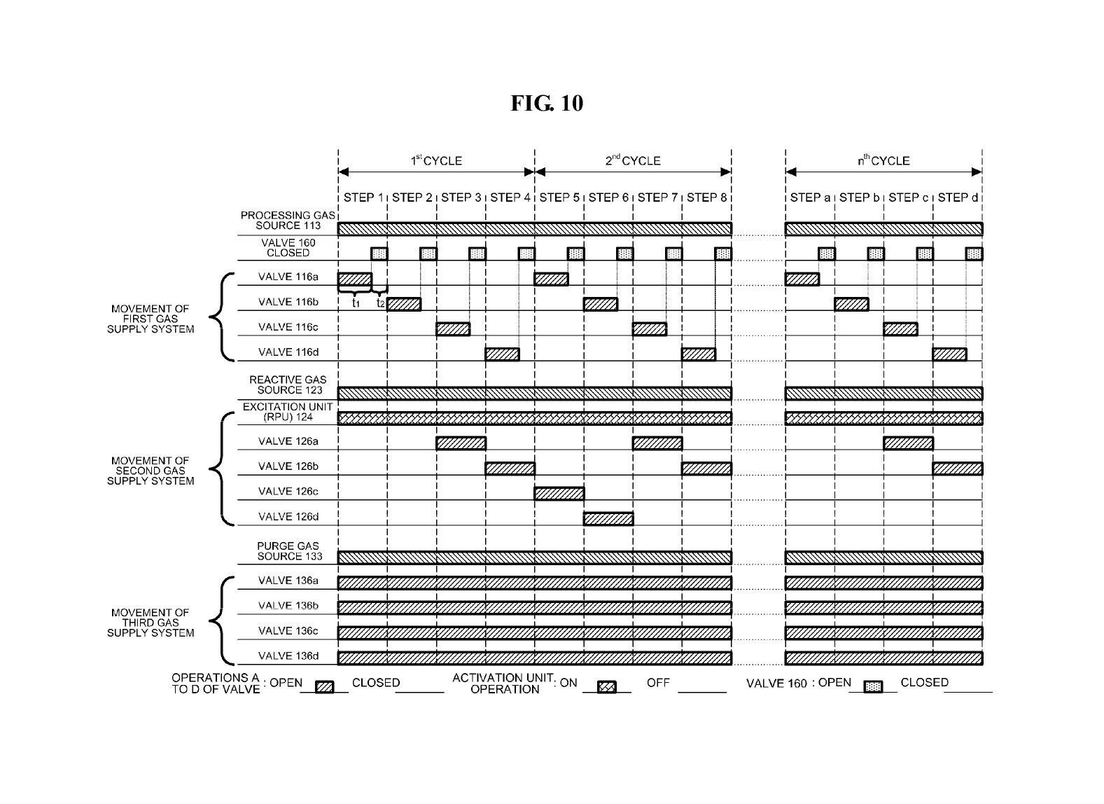

In addition, as shown in FIG. 10, the inert gas may be supplied during any one or both of the supply of the processing gas and the supply of the reactive gas into the substrate processing apparatuses. Since diffusivity of the gas into the processing chamber 201 can be improved by simultaneously supplying the inert gas, surface uniformity of processing of the wafer 200 can be improved. As the inert gas is supplied during any one or both of the supply of the processing gas and the supply of the inert gas, byproducts generated when each of the processing gas and the reactive gas is supplied can be removed by the inert gas. The byproducts may be, for example, ammonia chloride (NH₄Cl).

In addition, a difference in generation amounts of the byproducts in the shower head and the processing chamber is considered to be generated. Accordingly, purge timing of the shower head and purge timing of the processing chamber may be adjusted. In addition, an exhaust amount upon the purge may differ. Further, a supply amount of the inert gas upon the purge may differ.

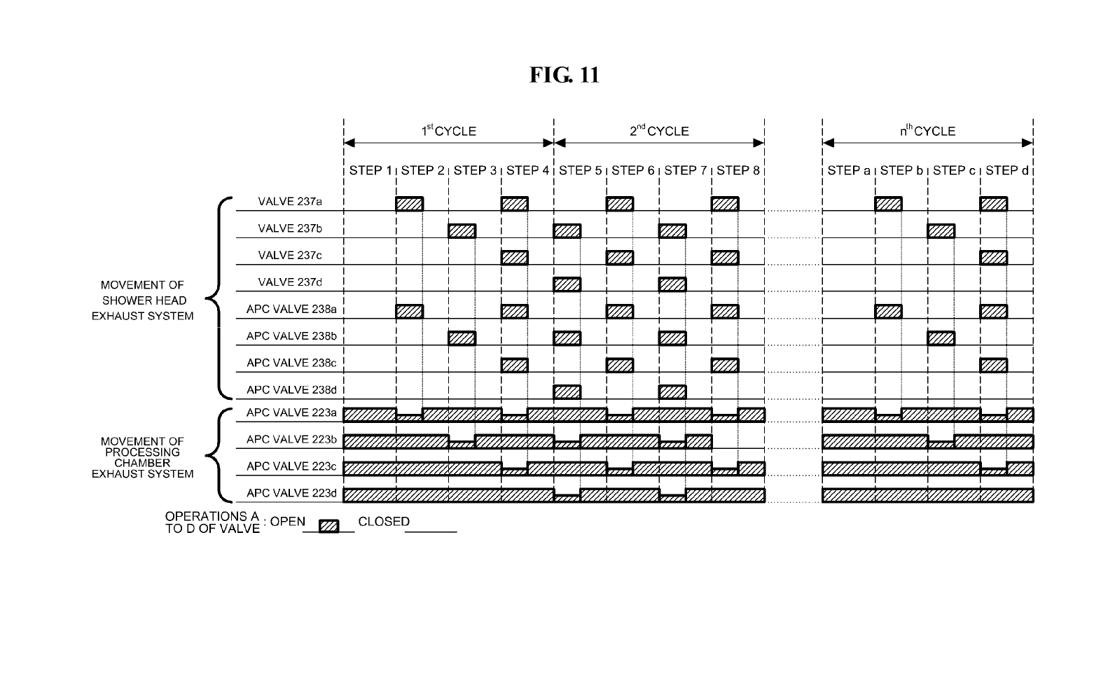

Next, valve operations of the exhaust systems of the steps will be described with reference to FIG. 11. As shown in FIG. 11, an opening angle of the APC valve of the processing chamber exhaust system is configured to be reduced when the exhaust is performed by the exhaust system of the shower head in each of the substrate processing apparatuses.

(3) Effects According to the Embodiment

According to the embodiment, one or a plurality of the following effects will be exhibited.

(a) Since the time period of supplying the gases can be reduced by supplying the processing gas into the processing chambers for a predetermined time, closing the valve and buffering the processing gas into the buffer tank, manufacturing throughput is improved.

(b) Since the ON/OFF control of the RPU is not needed as the supply of the reactive gas into the processing chambers is turned ON/OFF by manipulating the valve of the supply system of the reactive gas while the RPU is always ON, a time consumed for ON/OFF of the plasma can be reduced.

(c) As the exhaust conductance from the first exhaust system is increased to be larger than the conductance of the exhaust pump 224 via the processing chamber 201, the gas stuck to the buffer space 232 or the gas floating in the buffer space 232 is exhausted from the first exhaust system without entering the processing chamber 201.

(d) As the exhaust conductance from the second exhaust system is increased to be larger than the exhaust conductance from the first exhaust system via the shower head 230, the gas remaining in the processing chamber 201 can be exhausted.

(e) Since the flow directed toward the second exhaust system via the processing chamber 201 is not influenced by the first exhaust system because the valve of the first exhaust system is closed while the exhaust pump of the second exhaust system is operated in the purge process of the processing chamber, the inert gas can be more securely supplied onto the substrate, and removal efficiency of the gas remaining on the substrate can be further improved.

(f) The manufacturing throughput can be improved by substantially simultaneously performing the purge process of the shower head and the purge process of the processing chamber.

(g) As the purge process of the processing chamber starts before the purge process of the shower head is terminated, the processing gas or the reactive gas remaining in the shower head or the processing chamber can be reduced.

(h) Since a supply amount per unit time of each supply can be increased by installing the buffer tank 114 while saving a use amount of the processing gas, processing uniformity and manufacturing throughput of the wafer 200 can be improved.

(i) Since the activity-reduced reactive gas can be discharged by installing the ventilation line at the supply pipe of the reactive gas, processing quality or uniformity of the wafer 200 can be improved.

(k) When the activated reactive gas is sequentially supplied into the plurality of processing chambers, as the valves connected to the processing chambers are opened and closed in a state in which the activation unit is turned ON, the ON/OFF time of the activation unit can be reduced to improve the manufacturing throughput.

(l) As the inert gas is supplied when any one of both of the processing gas and the reactive gas is supplied, diffusivity of the processing gas or the reactive gas can be improved. In addition, since the byproducts can be removed, processing quality, processing uniformity and manufacturing throughput of the substrate can be improved.

(m) As the buffer tank is installed at a rear end of the evaporator, particles generated while the pressure in the evaporator is increased can be reduced.

(n) As the buffer tank is installed, a pressure difference in the gas pipe or a pressure difference in the processing chamber can be attenuated.

In addition, while the manufacturing process of the semiconductor device has been described, the present invention according to the embodiment can be applied to another process in addition to the manufacturing process of the semiconductor device. For example, the present invention can be applied to, for example, a manufacturing process of a liquid crystal device, plasma processing of a ceramic substrate, or the like.

In addition, while the method of forming the film by alternately supplying the source gas and the reactive gas has been described, the present invention can be applied to another method. For example, the source gas and the reactive gas may be supplied such that the supply timings overlap.

In addition, while the film-forming processing has been described, the present invention can be applied to other processing. For example, the present invention can be applied even when the film formed on the surface of the substrate or the substrate passes through plasma oxidation processing or plasma nitration processing using the reactive gas only. In addition, the present invention can be applied to plasma annealing processing using the reactive gas only.

### Another Embodiment

While the example of forming the metal nitride film (the titanium nitride (TiN) film) used as the electrode or a barrier film using titanium chloride and ammonia has been described, the present invention is not limited thereto. For example, the film may be a high-k film. For example, the film may be a zirconium oxide (ZrₓO_{y}) film or a hafnium oxide (HfₓO_{y}) film.

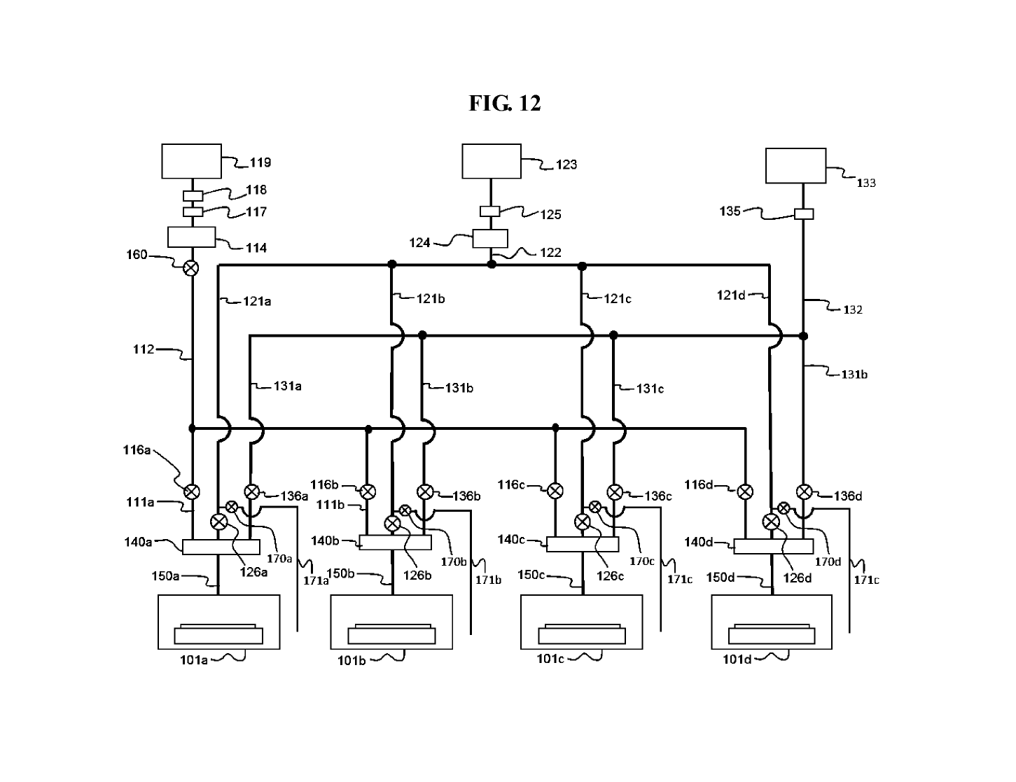

Hereinafter, an example of forming a hafnium oxide film will be described. When the hafnium oxide film is formed, TEMAHf is used as the first gas and oxygen gas (O₂) is used as the second gas. A supply sequence of the gas is configured substantially similarly to the above-mentioned embodiment. When the TEMAHf is supplied, in order to substantially remove TEMAHf molecules physically adsorbed after the supply, the supply of the first gas may be stopped during the supply process of the first gas and the extraordinarily adsorbed molecules may be eliminated. Since the TEMAHf is a liquid source material, the TEMAHf is gasified using the evaporator. Since the stoppage of the supply of the first gas cannot be easily controlled by the ON/OFF of the evaporator when the liquid source material is used, supply/stoppage of the gas is controlled by opening/closing the valve in a state in which the evaporator is ON. The inventor(s) found that the following problems are generated by the above-mentioned valve control. Since the pressure in the evaporator or the pipe of the rear end of the evaporator is increased to be higher than a vapor pressure during stoppage, the first gas is misted (liquefied) in the evaporator. The particles are generated by the mist. In addition, since a partial pressure of the TEMAHf is increased and causes insufficiency of evaporation, and the TEMAHf is supplied onto the substrate in a mist state, processing uniformity or precision of the substrate is decreased. FIG. 12 shows an apparatus configuration configured to solve the problems. As shown in FIG. 12, configurations of a first gas supply system, a second gas supply system and a third gas supply system are different from those of FIG. 7.

[First Gas Supply System]

The first gas supply system includes the processing chamber-side valves 116 (116a, 116b, 116c and 116d), the tank-side valve 160, the buffer tank 114, an evaporator 117, and a liquid flow rate control unit (LMFC) 118 installed from the processing chamber side. A liquid source material supply source 119 connected to the liquid flow rate control unit 118 may be configured to be included in the first gas supply system, and a supply pipe group 140 (140a, 140b, 140c and 140d) may be configured to be included therein. Here, Hf[N(C₂H₅)CH₃]₄ (tetrakisethylmethylaminohafnium: hereinafter, TEMAHf) serving as a liquid source material is supplied from the liquid source material supply source 119, a liquid flow rate is adjusted to a predetermined flow rate by the LMFC 118, and then the liquid is supplied into the evaporator 117. The liquid TEMAHf is gasified in the evaporator 117 to generate the processing gas. The processing gas is supplied into the processing chambers via the buffer tank. Here, a capacity of the buffer tank may be set such that a pressure of the buffer tank 114 during a gas supply stoppage time t₂ shown in FIGS. 9 and 10 is 50% or less of an increase in pressure from the pressure upon the gas supply. As described above, as the increase in pressure is attenuated by configuring the buffer tank, misting (liquefaction) of the gas can be prevented to suppress generation of the particles. In addition, a pressure variation of the processing chamber 201 can also be attenuated by attenuation of the pressure variation. For example, in the related art, in order to supply (flash flow) a large amount of a source gas into the processing chamber 201 within a predetermined time, the gas was stored in a tank and the valve was opened to supply the gas. In the method of the related art, since a pressure value immediately after the gas supply (upon starting of the supply) into the processing chamber is different from a pressure immediately after starting of the gas supply, in reality, an amount of the gas supplied to the substrate cannot be easily controlled. However, like the embodiment, since the pressure variation can be suppressed by attenuation of the pressure variation in the processing chamber 201, controllability of the pressure value upon actual processing or the gas supply amount to the substrate can be improved. In addition, as the gas supply amount to the substrate is clarified, the amount of the extra gas physically adsorbed to the substrate or the purge time for purging (removing) the extra gas can be easily adjusted. In addition, as the apparatus is configured not to abruptly increase the pressure in the processing chamber 201, introduction of any one or both of the first gas and the second gas into the conveyance space 203 can be suppressed to suppress generation of the particles in the conveyance space 203.

[Second Gas Supply System]

A second gas supply system is constituted by the processing chamber-side valves 126 (126a, 126b, 126c and 126d), the RPU 124, and the mass flow controller 125 connected from the processing chamber side. The reactive gas source 123 may be configured to be included in the second gas supply system. Activated oxygen gas (O₂) serving as a reactive gas is supplied from the second gas supply system.

[Third Gas Supply System]

A third gas supply system is constituted by the processing chamber-side valve 136 (136a, 136b, 136c and 136d) and the mass flow controller 135 connected from the processing chamber side. The purge gas source 133 may be configured to be included in the third gas supply system. Similar to the above-mentioned embodiment, the purge gas (the inert gas) can be supplied from the third gas supply system.

Since the pressure difference in the evaporator or the processing chamber can be attenuated by the gas supply common pipe or the buffer tank according to the above-mentioned configuration, an abrupt pressure variation in each of the processing chambers can be suppressed.

In addition, while the buffer tank of the above-mentioned embodiment is serially installed with respect to the gas supply source, the present invention is not limited thereto. For example, the buffer tank may be installed at the gas supply common pipe in parallel, and the gas may be supplied to the buffer tank when the pressure is to be attenuated.

According to the substrate processing system, the method of manufacturing the semiconductor device and the non-transitory computer-readable recording medium of the present invention, characteristics of the film formed on the substrate can be improved, and manufacturing throughput can be improved.

### Exemplary Modes of the Invention

Hereinafter, preferable modes of the present invention will be supplementarily stated.

<Supplementary Note 1>

According to a mode, the present invention provides a substrate processing system including:

a plurality of processing chambers accommodating substrates;

a processing gas supply system configured to supply a processing gas into the plurality of processing chambers in sequence;

a reactive gas supply system configured to supply an activated reactive gas into the plurality of processing chambers in sequence;

a buffer tank installed at the processing gas supply system; and

a control unit configured to control the processing gas supply system and the reactive gas supply system to alternately supply the processing gas and the reactive gas into each of the plurality of processing chambers in a manner that a time period of supplying the reactive gas into one of the plurality of processing chambers is equal to a sum of a time period of supplying the processing gas into the one of the plurality of processing chambers and a time period of supplying the processing gas into the buffer tank.

<Supplementary Note 2>

In the substrate processing system according to Supplementary Note 1, it is preferable that the control unit is configured to control the processing gas supply system to supply the processing gas into the buffer tank after a supply of the processing gas into the one of the plurality of processing chambers is stopped.

<Supplementary Note 3>

The substrate processing system according to Supplementary Note 1 may further include a purge gas supply system configured to supply a purge gas into the plurality of processing chambers,

wherein the control unit is configured to control the processing gas supply system and the purge gas supply system to supply the purge gas onto the substrate after the processing gas is supplied into the buffer tank.

<Supplementary Note 4>

The substrate processing system according to Supplementary Note 3 may further include a shower head installed at each of the plurality of processing chambers,

wherein the control unit is configured to control the processing gas supply system and the purge gas supply system to purge an inside of the shower head while the processing gas is supplied into the buffer tank.

<Supplementary Note 5>

The substrate processing system according to Supplementary Note 1 may further include a first exhaust unit installed at each of the plurality of processing chambers and configured to exhaust an inside atmosphere of each of the plurality of processing chambers,

wherein the control unit is configured to control the processing gas supply system, the reactive gas supply system and the first exhaust unit to purge the inside of the one of the plurality of processing chambers between a supply of the processing gas into the one of the plurality of processing chambers and a supply of the reactive gas into the one of the plurality of processing chambers.

<Supplementary Note 6>

The substrate processing system according to Supplementary Note 1 may further include an inert gas supply system configured to supply an inert gas into the plurality of processing chambers,

wherein the control unit is configured to control the processing gas supply system, the reactive gas supply system and the inert gas supply system to purge the inside of the processing chamber between a supply of the processing gas and a supply of the reactive gas into each of the processing chambers.

<Supplementary Note 7>

The substrate processing system according to Supplementary Note 1 may further include a shower head configured to supply the processing gas and the reactive gas into the plurality of processing chambers and including a second exhaust unit,

wherein the control unit is configured to control the processing gas supply system, the reactive gas supply system and the second exhaust unit to purge the inside of the shower head between a supply of the processing gas and a supply of the reactive gas.

<Supplementary Note 8>

In the substrate processing system according to Supplementary Note 7, it is preferable that the control unit is configured to control the first exhaust unit and the second exhaust unit to purge the inside of the one of the plurality of processing chambers after the inside of the shower head is purged.

<Supplementary Note 9>

In the substrate processing system according to Supplementary Note 7, it is preferable that the control unit is configured to control the first exhaust unit and the second exhaust unit to start a purge of the inside of the processing chamber before a purge of the shower head is terminated.

<Supplementary Note 10>

In the substrate processing system according to Supplementary Note 7 to Supplementary Note 9, it is preferable that the control unit is configured to control the first exhaust unit and the second exhaust unit such that exhaust conductance in the shower head becomes larger than conductance in the processing chamber when the inside of the shower head is purged.

<Supplementary Note 11>

In the substrate processing system according to Supplementary Note 7 to Supplementary Note 10, it is preferable that the control unit is configured to control the first exhaust unit and the second exhaust unit such that the exhaust conductance in the processing chamber becomes larger than the exhaust conductance of the shower head when the inside of the processing chamber is purged.

<Supplementary Note 12>

The substrate processing system according to Supplementary Note 1 may further include an activation unit installed at the reactive gas supply system and configured to excite the reactive gas,

wherein the control unit is configured to control the reactive gas supply system and the activation unit such that the activation unit is maintained in an ON state while the reactive gas is supplied into any one of the processing chambers.

<Supplementary Note 13>

The substrate processing system according to Supplementary Note 1 may further include an inert gas supply system configured to supply an inert gas into the plurality of processing chambers,

wherein the control unit is configured to control the processing gas supply system, the reactive gas supply system and the inert gas supply system such that the inert gas is supplied during any one or both of supply of the processing gas and supply of the reactive gas.

<Supplementary Note 14>

According to another mode, the present invention provides a method of manufacturing a semiconductor device, the method including:

(a) supplying a processing gas into a plurality of processing chambers in sequence for a first time period;

(b) supplying the processing gas into a buffer tank installed at a gas supply pipe connected to each of the plurality of processing chambers for a second time period; and

(c) supplying an activated reactive gas into the plurality of processing chambers in sequence for a time period equal to a sum of the first time period and the second time period.

<Supplementary Note 15>

In the method of manufacturing the semiconductor device according to Supplementary Note 14, it is preferable that the step (b) is performed after a supply of the processing as in the step (a) is stopped.

<Supplementary Note 16>

The method of manufacturing the semiconductor device according to Supplementary Note 14 may further include supplying a purge gas onto the substrate after performing the step (b).

<Supplementary Note 17>

In the method of manufacturing the semiconductor device according to Supplementary Note 16, it is preferable that a shower head is installed at each of the plurality of processing chambers, and

the method may further include purging the shower head during a supply of the processing gas into the buffer tank.

<Supplementary Note 18>

According to still another mode, the present invention provides a program executable by a computer, the program including:

(a) supplying a processing gas into a plurality of processing chambers in sequence for a first time period;

(b) supplying the processing gas into a buffer tank installed at a gas supply pipe connected to each of the plurality of processing chambers for a second time period; and

(c) supplying an activated reactive gas into the plurality of processing chambers in sequence for a time period equal to a sum of the first time period and the second time period a sequence of supplying a processing gas sequentially into each of a plurality of processing chambers for a predetermined first time;

<Supplementary Note 19>

According to still another mode, the present invention provides a substrate processing system including:

a plurality of processing chambers accommodating substrates;

a processing gas supply system configured to supply a processing gas sequentially into the plurality of processing chambers;

a reactive gas supply system configured to supply an activated reactive gas sequentially into the plurality of processing chambers;

a buffer tank installed at the processing gas supply system; and

a control unit configured to control the processing gas supply system and the reactive gas supply system such that a time of supplying the reactive gas into the processing chambers of one side of the plurality of processing chambers becomes a total time of a time of supplying the processing gas into the processing chambers of the other side of the plurality of processing chambers and a time of supplying the processing gas into the buffer tank, and the processing gas and the reactive gas are alternately supplied into the plurality of processing chambers.

<Supplementary Note 20>

According to still another mode, the present invention provides a substrate processing system including:

a plurality of processing chambers accommodating substrates;

a processing gas supply system configured to supply a processing gas sequentially into the plurality of processing chambers;

a reactive gas supply system configured to supply an activated reactive gas sequentially into the plurality of processing chambers;

a buffer tank installed at a processing gas supply common pipe connected to the plurality of processing chambers; and

a control unit configured to control the processing gas supply system and the reactive gas supply system such that a time of supplying the reactive gas into the processing chambers of one side in the plurality of processing chambers becomes a total time of a predetermined first time of supplying the processing gas into the processing chamber of the other side in the plurality of processing chambers and a predetermined second time of stopping the supply of the processing gas into the processing chambers and supplying the processing gas into the buffer tank, and the processing gas and the reactive gas are alternately supplied into the plurality of processing chambers.

<Supplementary Note 21>

According to still another mode, the present invention provides a method of manufacturing a semiconductor device, the method including:

(a) supplying a processing gas sequentially into each of a plurality of processing chambers for a predetermined first time;

(b) supplying a processing gas into a buffer tank installed at a processing gas supply common pipe connected to each of the processing chambers for a predetermined second time; and

(c) supplying an activated reactive gas sequentially to each of the plurality of processing chambers for a total time of the predetermined first time and the predetermined second time.

<Supplementary Note 22>

According to still another mode, the present invention provides a program configured executable by a computer, including:

(a) supplying a processing gas sequentially into each of a plurality of processing chambers for a predetermined first time;

(b) supplying a processing gas into a buffer tank installed at a processing gas supply common pipe connected to each of the processing chambers for a predetermined second time; and

(c) supplying an activated reactive gas sequentially to each of the plurality of processing chambers for a total time of the predetermined first time and the predetermined second time, in a computer.

<Supplementary Note 23>

According to still another mode, the present invention provides a non-transitory computer-readable recording medium storing a program executable by a computer, the program including:

(a) supplying a processing gas sequentially into each of a plurality of processing chambers for a predetermined first time;

(b) supplying a processing gas into a buffer tank installed at a processing gas supply common pipe connected to each of the processing chambers for a predetermined second time; and

(c) supplying an activated reactive gas sequentially to each of the plurality of processing chambers for a total time of the predetermined first time and the predetermined second time.

<Supplementary Note 24>

According to still another mode, the present invention provides a semiconductor device manufacturing apparatus including:

a processing chamber in which a substrate is accommodated;

a processing gas supply system configured to supply a processing gas sequentially into the processing chamber;

a reactive gas supply system configured to supply an activated reactive gas sequentially into the processing chamber;

a buffer tank installed at a processing gas supply common pipe connected to the processing chamber; and

a control unit configured to control the processing gas supply system and the reactive gas supply system such that a time of supplying the reactive gas into the processing chamber becomes a total time of a predetermined first time of supplying the processing gas into the processing chamber and a predetermined second time of stopping supply of the processing gas and supplying the processing gas into the buffer tank, and a supply timing is adjusted to alternately supply the processing gas and the reactive gas into the processing chamber.

<Supplementary Note 25>

According to still another mode, the present invention provides a substrate processing system including:

at least two processing chambers accommodating substrates;

a processing gas supply system configured to supply a processing gas sequentially into the at least two processing chambers;

a reactive gas supply system configured to supply an activated reactive gas sequentially into the at least two processing chambers;

a buffer tank installed at a processing gas supply common pipe connected to the at least two processing chambers; and

a control unit configured to control the processing gas supply system and the reactive gas supply system such that a time of supplying the reactive gas into the processing chamber of one side in the at least two processing chambers becomes a total time of a predetermined first time of supplying the processing gas into the processing chamber of the other side in the at least two processing chambers and a predetermined second time of stopping supply of the processing gas into the processing chamber and supplying the processing gas into the buffer tank, and the processing gas and the reactive gas are alternately supplied into the at least two processing chambers.

<Supplementary Note 26>

According to still another mode, the present invention provides a substrate processing system including:

a first processing chamber and a second processing chamber accommodating substrates;

a processing gas supply system configured to supply a processing gas sequentially into the first processing chamber and the second processing chamber;

a reactive gas supply system configured to supply an activated reactive gas sequentially into the first processing chamber and the second processing chamber;

a buffer tank installed at a processing gas supply common pipe connected to the first processing chamber and the second processing chamber; and

a control unit configured to control the processing gas supply system and the reactive gas supply system such that a time of supplying the reactive gas into the second processing chamber becomes a total time of a predetermined first time of supplying the processing gas into the first processing chamber and a predetermined second time of stopping supply of the processing gas into the processing chamber and supplying the processing gas into the buffer tank, and the processing gas and the reactive gas are alternately supplied into the first processing chamber and the second processing chamber.

What is claimed is:

1. A method of manufacturing a semiconductor device, the method comprising:
(a) supplying a processing gas into a plurality of processing chambers in sequence for a first time period;
(b) supplying the processing gas into a buffer tank installed at a gas supply pipe connected to each of the plurality of processing chambers for a second time period; and
(c) supplying an activated reactive gas into the plurality of processing chambers in sequence for a time period equal to a sum of the first time period and the second time period.

2. The method according to claim 1, wherein the step (b) is performed after a supply of the processing gas in the step (a) is stopped.

3. The method according to claim 1, further comprising supplying a purge gas onto the substrate after performing the step (b).

4. The method according to claim 1, further comprising starting a purge of an inside of a shower head installed at each of the plurality of processing chambers while or after performing the step (b).

5. The method according to claim 3, further comprising starting a purge of an inside of a shower head installed at each of the plurality of processing chambers between the step (b) and the step (e) or while performing the step (b).

6. A non-transitory computer-readable recording medium storing a program executable by a computer, the program comprising:
(a) supplying a processing gas into a plurality of processing chambers in sequence for a first time period;
(b) supplying the processing gas into a buffer tank installed at a gas supply pipe connected to each of the plurality of processing chambers for a second time period; and
(c) supplying an activated reactive gas into the plurality of processing chambers in sequence for a time period equal to a sum of the first time period and the second time period.

7. The non-transitory computer-readable recording medium according to claim 6, wherein the sequence (b) is performed after a supply of the processing gas in the sequence (a) is stopped.

8. The non-transitory computer-readable recording medium according to claim 6, wherein the program further comprises supplying a purge gas onto the substrate after performing the sequence (b).

9. The non-transitory computer-readable recording medium according to claim 6, wherein the program further comprises starting a purge of an inside of a shower head installed at each of the plurality of processing chambers while or after performing the sequence (b).

10. The non-transitory computer-readable recording medium according to claim 8, wherein the program further comprises starting a purge of an inside of a shower head installed at each of the plurality of processing chambers between the sequence (b) and the sequence (e) or while performing the sequence (b).
